(19) United States
(12) Patent Application Publication
(10) Pub. No.: US 2021/0218168 A1
(43) Pub. Date: Jul. 15, 2021

(54) ELECTRICAL CONNECTOR

(71) Applicant: LOTES CO., LTD, Keelung (TW)

(72) Inventors: Xiao Guang Gui, Keelung (TW); Xiang Xiong Liu, Keelung (TW)

(21) Appl. No.: 17/030,825

(22) Filed: Sep. 24, 2020

(30) Foreign Application Priority Data
Jan. 14, 2020 (CN) 202020087581.8

(51) Int. Cl. H01R 12/70; H01R 13/633

(52) U.S. Cl. CPC H01R 12/7076; H01R 13/633

(57) ABSTRACT

An electrical connector includes an insulating body having a bottom wall, an accommodating cavity provided above the bottom wall, and two side walls at left and right sides of the accommodating cavity. Each side wall has a reserved slot running through the corresponding side wall in a left-right direction and in communication with the accommodating cavity. The insulating body has an oblique surface at a bottom portion of the reserved slot, which is provided obliquely downward and outward, and has an inner edge and an outer edge. The outer edge is lower than a top surface of the bottom wall. Each side wall is further concavely provided with multiple notches at front and back sides of the corresponding reserved slot. Each notch runs along the left-right direction and upward through the corresponding side wall. A lower edge of each notch is higher than the corresponding oblique surface.

### CROSS-REFERENCE TO RELATED PATENT APPLICATION

This non-provisional application claims priority to and the benefit of, pursuant to 35 U.S.C. § 119(a), patent application Serial No. CN202020087581.8 filed in China on Jan. 15, 2020. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present invention relates to an electrical connector, and particularly to an electrical connector which is convenient to retrieve a chip module mounted to the insulating body therein.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

An existing electrical connector is used to be electrically connected to a chip module. The electrical connector includes an insulating body. The insulating body has a bottom wall, an accommodating cavity provided above the bottom wall, four side walls protruding upward from the bottom wall and provided around the accommodating cavity, and a supporting block protruding upward from the bottom wall. The supporting block is provided in the accommodating cavity to support the chip module. Each of the two side walls opposite to each other respectively forms a reserved slot downward concavely provided on the top surface thereof. The reserved slot runs through the corresponding side wall along a left-right direction. Two interior walls at a front side and a back side of the reserved slot extend as vertical plain surfaces. The insulating body is provided with a horizontal surface at a bottom portion of the reserved slot. The horizontal surface and a top surface of the supporting block are provided to be flush and extend on a same horizontal plane. That is, the horizontal surface is provided higher than the bottom wall.

However, in the structure as described above, the horizontal surface at the bottom portion of the reserved slot and the top surface of the supporting block are located on the same horizontal plane. When the fingers of a user are disposed in two reserved slots to retrieve the chip module, the space receiving each of the fingers in a vertical direction is small. Further, the user may only move the fingers along the horizontal surface toward the chip module in the insulating body to clamp and retrieve the chip module in the insulating body, and in the clamping and retrieving process, the user may only clamp and retrieve the chip module using only the fingertips of the fingers, and the fingertips are not lower than the bottom surface of the chip module. Moreover, the fingertips may only clamp and retrieve the chip module toward the left and right side surfaces of the chip module along the left-right direction, which is not conductive for the human hand of the user to apply a stable clamping force to the chip module, such that the chip module may easily slip and fall from the fingertips of the user, thus damaging the terminals, and causing damage to the chip module.

Therefore, a heretofore unaddressed need to design a new electrical connector exists in the art to address the aforementioned deficiencies and inadequacies.

### SUMMARY

The present invention is directed to an electrical connector, in which a space for a user to retrieve the chip module in the insulating body is enlarged.

To achieve the foregoing objective, the present invention adopts the following technical solutions.

An electrical connector is configured to be electrically connected to a chip module. The electrical connector includes: an insulating body, having a bottom wall, an accommodating cavity provided above the bottom wall, and two side walls protruding upward relative to the bottom wall and provided at a left side and a right side of the accommodating cavity; and a plurality of terminals, provided in the insulating body, and configured to be electrically connected to the chip module, wherein each of the two side walls is correspondingly formed with a reserved slot downward concavely provided on a top surface of each of the two side walls, the reserved slot runs through a corresponding one of the two side walls in a left-right direction and is in communication with the accommodating cavity, the insulating body is provided with an oblique surface at a bottom portion of the reserved slot, the oblique surface is provided obliquely downward and outward, the oblique surface has an inner edge and an outer edge provided opposite to each other in the left-right direction, the outer edge is provided farther away from the accommodating cavity than the inner edge, the outer edge is provided to be lower than a top surface of the bottom wall, each of the two side walls is further concavely provided with two notches at a front side and a back side of the corresponding reserved slot respectively in a front-rear direction, each of the two notches runs along the left-right direction and upward through the corresponding one of the two side walls, and a lower edge of each of the two notches is provided to be higher than the corresponding oblique surface in a vertical direction.

In certain embodiments, each of the two notches has a curved surface, two interior walls are respectively provided at the front side and the back side of the reserved slot, and the curved surface of each of the two notches is downward connected to a corresponding one of the two interior walls.

In certain embodiments, each of the two notches further has a plain surface extending vertically, the plain surface is located above the curved surface and is connected to the curved surface, and the plain surface of each of the two notches is upward connected to the top surface of the corresponding one of the two side walls.

In certain embodiments, the curved surface of one of the two notches at the front side and the back side of the reserved slot of each of the two side walls is downward concavely provided with a groove, and the groove is in communication with the corresponding reserved slot in the front-rear direction.

In certain embodiments, the groove extends downward to pass beyond the oblique surface.

In certain embodiments, each of the two side walls is provided with a foolproof block protruding into the accommodating cavity to match with a cutout of the chip module, the foolproof block and the other of the notches not provided with the groove are located at a same side of the corresponding reserved slot in the front-rear direction, and the foolproof block is provided to be farther away from the corresponding reserved slot than the other of the notches not provided with the groove.

In certain embodiments, the two grooves located on the two side walls are provided to align in the left-right direction.

In certain embodiments, the oblique surface is further downward concavely provided with a recess, and the recess extends toward the accommodating cavity in the left-right direction and passes beyond the inner edge.

In certain embodiments, the oblique surface is further downward concavely provided with a plurality of concave portions, the concave portions are provided in a row along the front-rear direction, and the concave portions are located at a same side of the recess in the front-rear direction.

In certain embodiments, each of the two side walls is provided with an opening slot at the front side or the back side of the corresponding reserved slot, the opening slot is provided to be farther away from the corresponding reserved slot than one of the two notches located at a same side of the corresponding reserved slot in the front-rear direction, and the opening slot is in communication with the accommodating cavity along the left-right direction.

In certain embodiments, the inner edge is provided to be farther away from the accommodating cavity than an inner surface of the corresponding one of the two side walls.

In certain embodiments, the outer edge is provided to be flush with an outer surface of the insulating body.

In certain embodiments, the oblique surface is provided obliquely downward and outward from the top surface of the bottom wall.

In certain embodiments, the insulating body further comprises a supporting block protruding upward relative to the bottom wall, the supporting block is located in the accommodating cavity to support the chip module, and a top surface of the supporting block is lower than the top surface of each of the two side walls and higher than the inner edge of the oblique surface in the vertical direction.

In certain embodiments, the lower edge of each of the two notches and the top surface of the supporting block are located on a same horizontal plane.

In certain embodiments, the supporting block is provided to align with the two reserved slots of the two side walls in the left-right direction.

In certain embodiments, the insulating body is provided with two supporting blocks, the two supporting blocks are provided at a left side and a right side of the accommodating cavity, each of the two supporting blocks is provided to be adjacent to a corresponding one of the two reserved slots of the two side walls, a distance between each of the two supporting blocks and one of two interior walls at the front side and the back side of the corresponding one of the two reserved slots of the two side walls is less than a distance between each of the two supporting blocks and the other of the two interior walls at the front side and the back side of the corresponding one of the two reserved slots of the two side walls.

In certain embodiments, the supporting block is provided to be farther away from the corresponding inner edge than an inner surface of the corresponding one of the two side walls, and the supporting block and the inner surface of the corresponding one of the two side walls are provided separately in the left-right direction.

In certain embodiments, the electrical connector further includes a clip tool, wherein the clip tool includes an upper cover and a clip seat, the clip seat is provided at one of a front side and a back side of the insulating body, and the upper cover is provided above the insulating body and rotates relative to the clip seat at one of a front side and a back side of the accommodating cavity.

In certain embodiments, the insulating body is provided with two end walls respectively at a front side and a back side of the accommodating cavity, each of the two end walls connects the two side walls, each of the two end walls is correspondingly formed with a through slot downward concavely provided on a top surface of each of the two end walls, the through slot runs through a corresponding one of the two end walls along the front-rear direction and is in communication with the accommodating cavity, the insulating body is provided with an inclined surface at a bottom portion of the through slot, and the inclined surface is provided obliquely downward and outward in the front-rear direction.

Compared with the related art, in certain embodiments of the present invention, the insulating body is provided with the oblique surfaces respectively at the bottom portions of the reserved slots. The oblique surfaces may guide the fingers of a user inward from outside thereof to move toward the chip module in the insulating body, and to move to the left side and the right side of the chip module, thus enhancing the convenience for the user to retrieve the chip module in the insulating body. Further, the outer edge of each of the oblique surfaces at the bottom portions of the reserved slots is provided to be lower than the top surface of the bottom wall, and in the vertical direction, the space receiving each of the fingers of the user is enlarged, and the user may retrieve the chip module using the finger pulps. Compared to the related art in which the user retrieves the chip module using the fingertips, the finger pulps allow the human hand to stably apply a clamping force to the chip module, such that the chip module does not easily slip and fall from the fingers of the user. Moreover, each of the two side walls is further concavely provided with the notches at the front side and the back side of the corresponding reserved slot in the front-rear direction. Compared to the related art in which the two interior walls at the front side and the back side of the reserved slot extend as vertical plain surfaces, the space for each of the reserved slots in the front-rear direction is enlarged, which is convenient for receiving a large part of finger to retrieve the chip module in the insulating body, and further ensuring the chip module not to easily slip downward from the fingers of the user in the retrieving process.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a perspective exploded view of an electrical connector, a circuit board and a back plate according to certain embodiments of the present invention.

FIG. 2 is a perspective exploded view of the insulating body, the terminals and the chip module additionally provided in FIG. 1.

FIG. 3 is a perspective assembled view of FIG. 2.

FIG. 4 is a perspective view of the insulating body in FIG. 2 from another viewing angle.

FIG. 5 is an enlarged view of a portion A in FIG. 4.

FIG. 6 is a top view of FIG. 5.

FIG. 7 is a left view of FIG. 5.

FIG. 8 is an enlarged view of a portion B in FIG. 4.

FIG. 9 is a top view of FIG. 8.

FIG. 10 is a right view of FIG. 8.

FIG. 11 is an enlarged view of a portion C in FIG. 4.

FIG. 12 is a top view of FIG. 11.

FIG. 13 is a partially sectional view of FIG. 4 along a line D-D.

### DETAILED DESCRIPTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the terms “comprising”, “including”, “carrying”, “having”, “containing”, “involving”, and the like are to be understood to be open-ended, i.e., to mean including but not limited to.

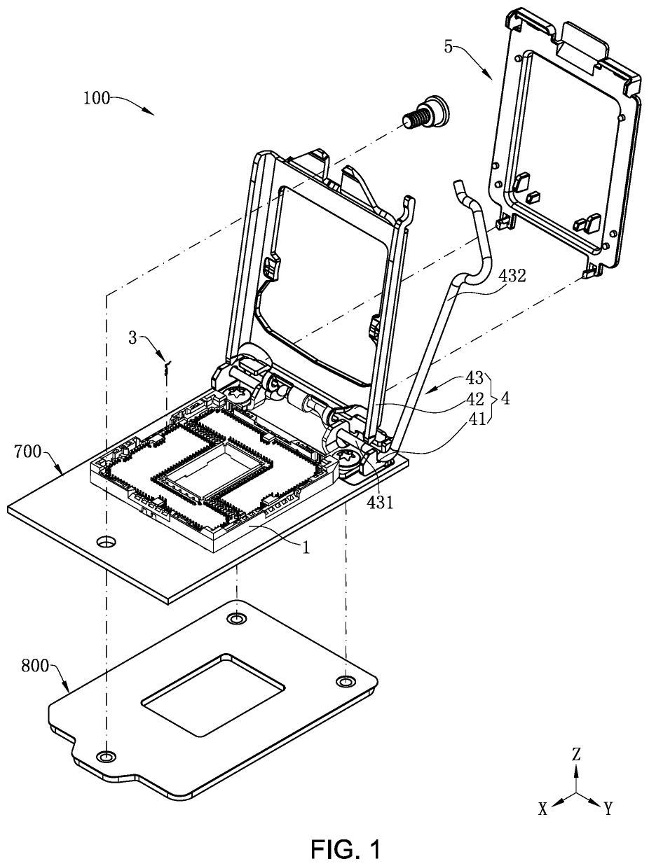

The description will be made as to the embodiments of the present invention in conjunction with the accompanying drawings in FIGS. 1-13. In accordance with the purposes of this invention, as embodied and broadly described herein, this invention, in one aspect, relates to an electrical connector.

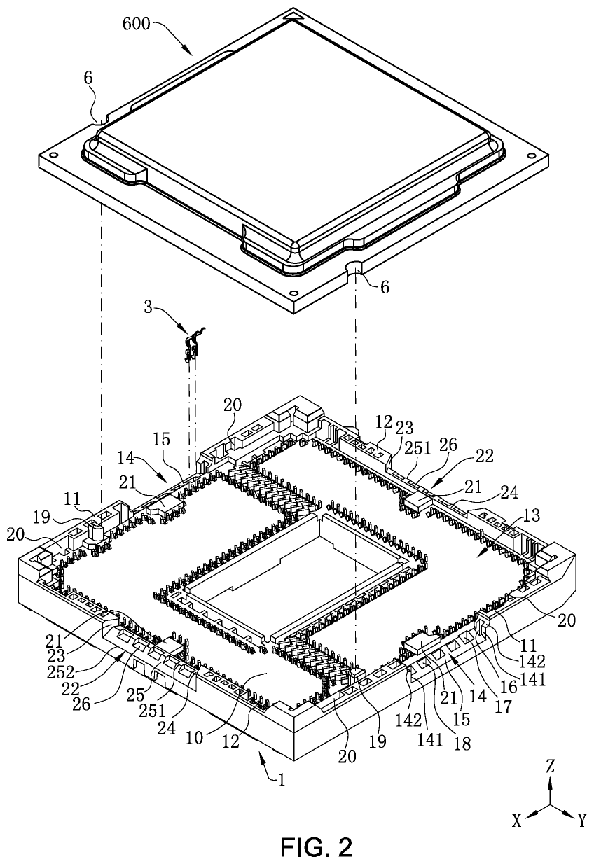

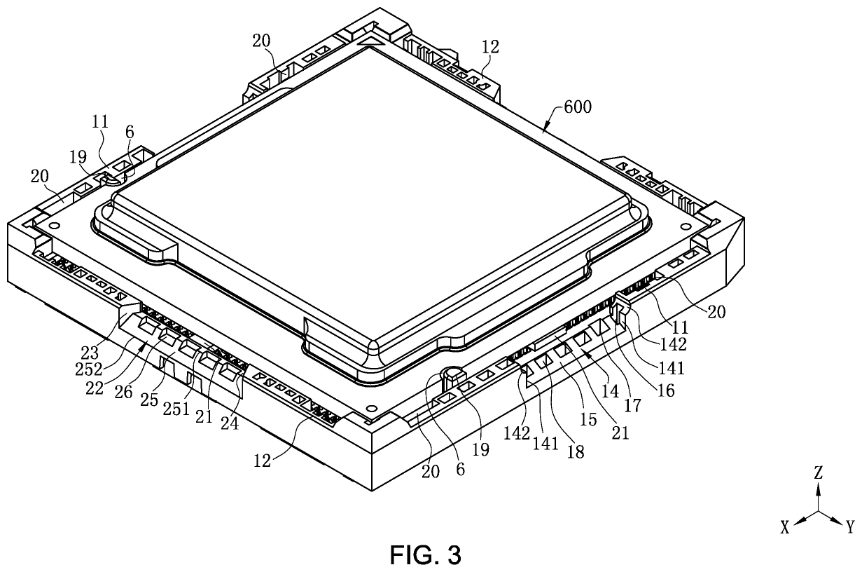

As shown in FIG. 1, FIG. 2 and FIG. 3, an electrical connector 100 according to certain embodiments of the present invention includes an insulating body 1 used to receive a chip module 600, a plurality of terminals 3 provided in the insulating body 1 and electrically connected upward to the chip module 600, a clip tool 4 clipping and pressing the chip module 600 stably to the insulating body 1, and a dust cover 5 provided above the clip tool 4 and used to perform dust proof to the insulating body 1. The insulating body 1 and the clip tool 4 are provided above a circuit board 700. The terminals 3 are electrically connected downward to the circuit board 700. A back plate 800 is provided below the circuit board 700 to fix and lock the clip tool 4 to the circuit board 700.

As shown in FIG. 2 and FIG. 3, the insulating body 1 includes a bottom wall 10, and two side walls 11 and two end walls 12 provided to extend upward from a top surface of the bottom wall 10. The two side walls 11 are provided separately in a left-right direction Y, and the two end walls 12 are provided separately in a front-rear direction X. Each of the two side walls 11 connects the two end walls 12 in the front-rear direction. The two side walls 11, the two end walls 12 and the bottom walls 10 are surroundingly provided to form an accommodating cavity 13 to receive the chip module 600. Specifically, the insulating body 1 in this embodiment is substantially in a rectangular shape.

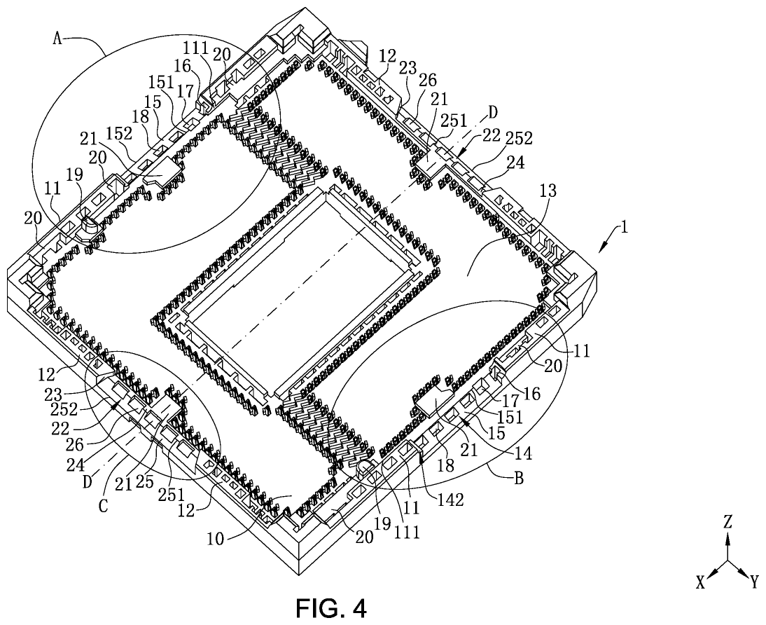

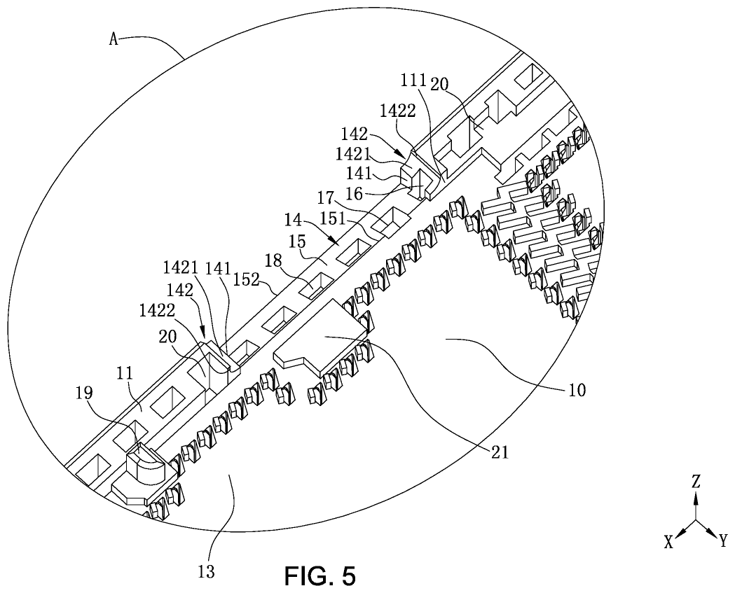

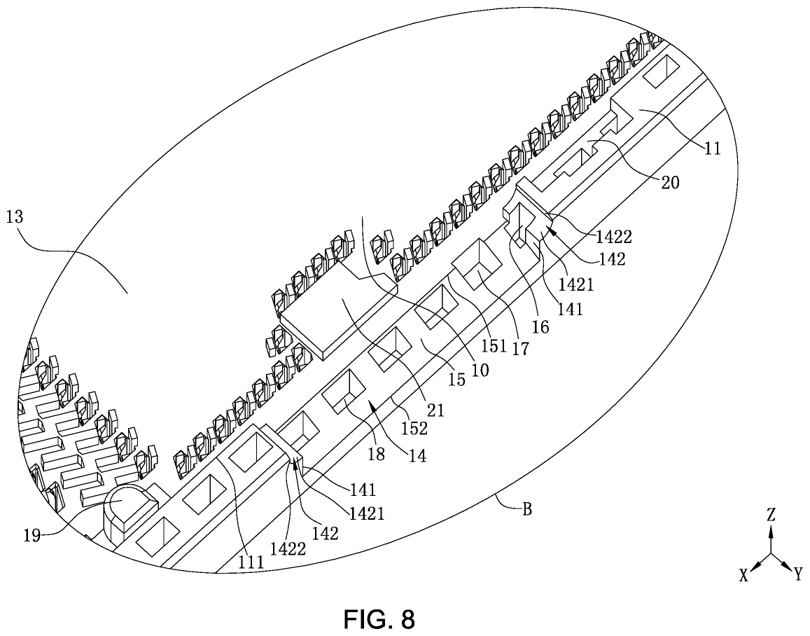

As shown in FIG. 4, FIG. 5 and FIG. 8, each of the two side walls 11 is correspondingly formed with a reserved slot 14 downward concavely provided on a top surface of each of the two side walls 11. The two reserved slots 14 of the two side walls 11 are provided opposite to each other along the left-right direction, and each reserved slot 14 is located substantially at a middle location of the corresponding side wall 11. The insulating body 1 is provided with two interior walls 141 at the front side and the back side of each reserved slot 14. That is, the two interior walls 141 are respectively provided at the front side and the back side of each reserved slot 14.

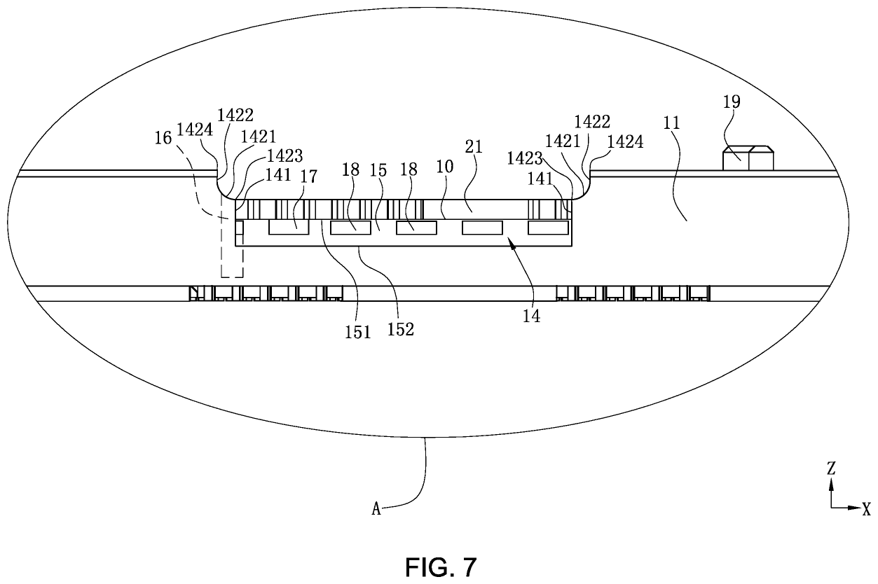

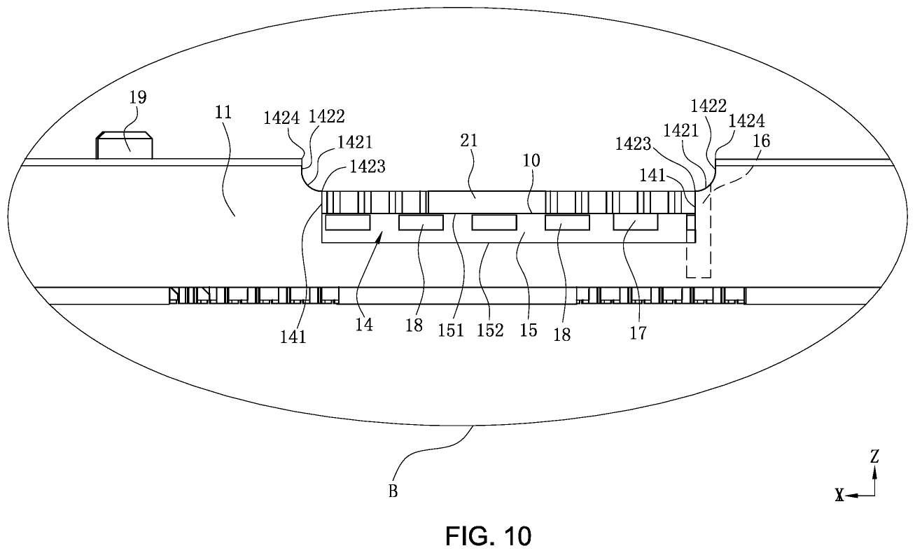

As shown in FIG. 7 and FIG. 10, each of the two side walls 11 is further concavely provided with two notches 142 at a front side and a back side of the corresponding reserved slot 14 in the front-rear direction X. That is, each of the two notches 142 is concavely formed on a corresponding interior wall 141 toward a direction away from the reserved slot 14 in the front-rear direction X. Each of the two notches 142 has a lower edge 1423 and an upper edge 1424, and the lower edge 1423 of each of the two notches 142 is connected with the corresponding interior wall 141 and is provided to be higher than the top surface of the bottom wall 10.

As shown in FIG. 4, FIG. 5 and FIG. 8, each of the two notches 142 runs along the left-right direction Y and upward through the corresponding side wall 11. That is, each of the two notches 142 is connected inward to an inner surface 111 of the corresponding side wall 11, and is connected outward to an outer surface of the corresponding side wall 11. In other words, each of the two notches 142 runs through the corresponding side wall 11 in a left-right direction Y. The upper edge 1424 of each of the two notches 142 is connected to the top surface of the corresponding side wall 11. Specifically, each of the two notches 142 includes a curved surface 1421 and a plain surface 1422 connected to each other in a vertical direction Z. The plain surface 1422 extends along the vertical direction Z, and the plain surface 1422 is located above the curved surface 1421. The plain surface 1422 is connected upward to the top surface of the corresponding side wall 11, and the curved surface 1421 is connected downward to the corresponding interior wall 141. In other embodiments, each of the two notches 142 may be provided only with the curved surface 1421. The curved surface 1421 is connected downward to the corresponding interior wall 141, and is connected upward to the top surface of the corresponding side wall 11.

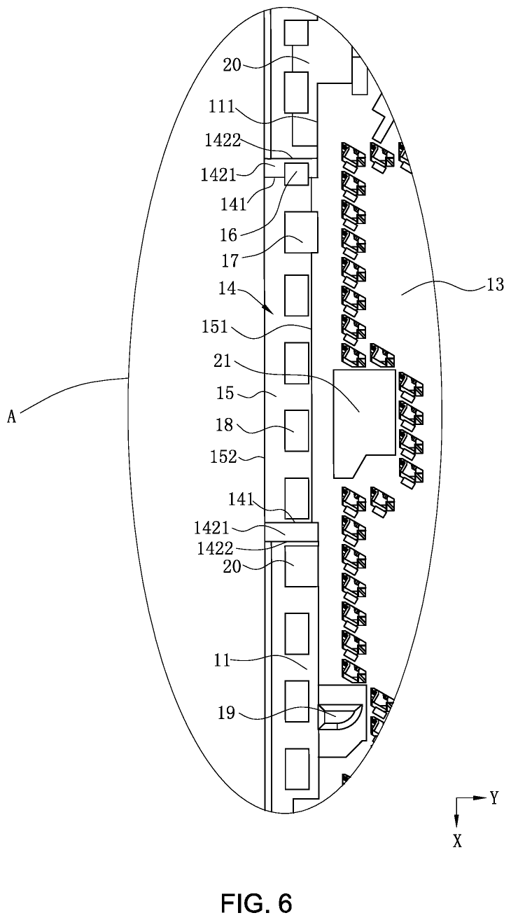

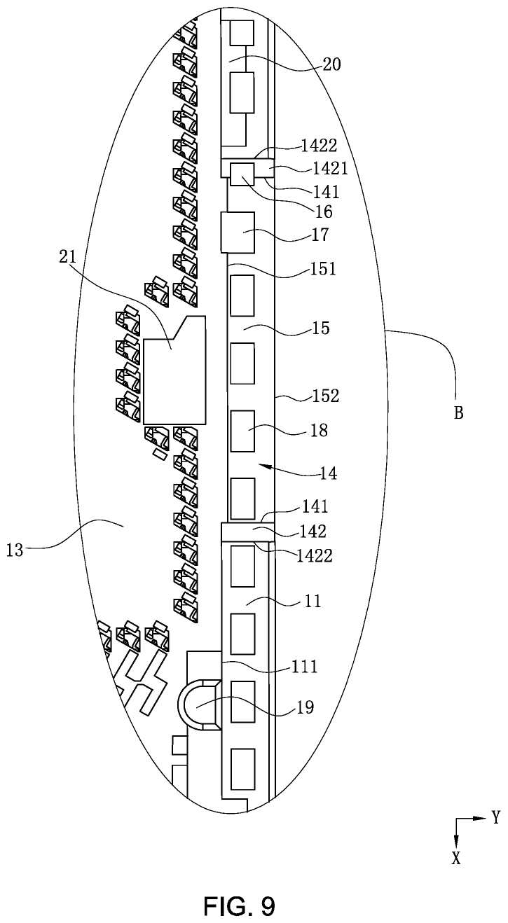

As shown in FIG. 4, FIG. 5 and FIG. 8, the insulating body 1 is provided with an oblique surface 15 at a bottom portion of each of the two reserved slots 14. The oblique surface 15 is provided obliquely downward and outward from the top surface of the bottom wall 10 in the left-right direction Y. Specifically, an inclined angle of the oblique surface 15 is 30°. The oblique surface 15 has an inner edge 151 and an outer edge 152 provided opposite to each other in the left-right direction Y. The outer edge 152 is provided farther away from the accommodating cavity 13 than the inner edge 151 in the left-right direction Y (also referring to FIG. 6 and FIG. 9). In the vertical direction Z, the inner edge 151 is flush with the top surface of the bottom wall 10, and the outer edge 152 is provided to be lower than the top surface of the bottom wall 10. Further, the lower edge 1423 of each of the two notches 142 is provided to be higher than the corresponding oblique surface 15 in the vertical direction Z (also referring to FIG. 7 and FIG. 10). The inner edge 151 is provided to be farther away from the accommodating cavity 13 than the inner surface 111 of the corresponding side wall 11 in the left-right direction Y (also referring to FIG. 6 and FIG. 9). The outer edge 152 is provided to be flush with an outer surface of the insulating body 1 in the left-right direction Y.

As shown in FIG. 4, FIG. 5 and FIG. 8, the insulating body 1 is downward concavely provided with a groove 16 only in one of the two notches 142 at one side of the reserved slot 14 of each of the two side walls 11 (also referring to FIG. 7 and FIG. 10), and the groove 16 is in communication with the corresponding reserved slot 14 in the front-rear direction X. The groove 16 is downward concavely provided on the curved surface 1421. The two grooves 16 located at the two side walls 11 are provided to align in the left-right direction Y. The groove 16 extends downward to pass beyond the corresponding oblique surface 15 along the vertical direction Z, and the portion of the groove 16 passing beyond the oblique surface 15 is recessed toward the corresponding oblique surface 15 along the front-rear direction X (also referring to FIG. 7 and FIG. 10). In this embodiment, the groove 16 is provided at the back side of the reserved slot 14. That is, the notch 142 at the front side of each of the two reserved slots 14 is not downward concavely provided with the groove 16 (also referring to FIG. 6 and FIG. 9). In other embodiments, it is also possible to downward concavely provide the groove 16 only in the notch 142 at the front side of the reserved slot 14, and not in the notch 142 at the backside of the reserved slot 14. Alternatively, it is also possible to provide two grooves 16 in the two notches 142 at both the front side and the back side of the reserved slot 14.

As shown in FIG. 4, FIG. 5 and FIG. 8, the insulating body 1 is further downward concavely provided with a recess 17 on each of the oblique surfaces 15. The recess 17 extends toward the accommodating cavity 13 in the left-right direction Y and passes beyond the inner edge 151 of the corresponding oblique surfaces 15 (also referring to FIG. 6 and FIG. 9). That is, in the left-right direction Y, a portion of the recess 17 is downward concavely formed on the corresponding oblique surface 15, and another portion of the recess 17 is downward concavely formed on the top surface of the bottom wall 10. The recess 17 is provided to be close to the corresponding groove 16 in the front-rear direction X, and is separated from the corresponding groove 16.

As shown in FIG. 4, FIG. 5 and FIG. 8, the insulating body 1 is further downward concavely provided with a plurality of concave portions 18 on each of the oblique surfaces 15. The concave portions 18 are provided in a row along the front-rear direction X, and the concave portions 18 are located at a same side of the corresponding recess 17 in the front-rear direction X (also referring to FIG. 6 and FIG. 9). That is, the concave portions 18 are provided to be close to the notch 142 at the front side of the corresponding reserved slot 14 than the recess 17.

As shown in FIG. 4, FIG. 5 and FIG. 8, the insulating body 1 is provided with a foolproof block 19 on each of the two side walls 11 protruding into the accommodating cavity 13. The foolproof block 19 and the notch 142 not provided with the groove 16 are located at a same side of the corresponding reserved slot 14 in the front-rear direction X (also referring to FIG. 6 and FIG. 9). Specifically, the foolproof block 19 and the notch 142 not provided with the groove 16 are located at the front side of the corresponding reserved slot 14. Further, the foolproof block 19 is provided to be farther away from the corresponding reserved slot 14 than the notch 142 not provided with the groove 16. Since the reserved slot 14 is located at the middle location of the corresponding side wall 11 in the front-rear direction X, the foolproof block 19 is located at a front side of the center point of the corresponding side wall 11.

As shown in FIG. 2 and FIG. 3, each of the left side and the right side of the chip module 600 is concavely provided with a cutout 6. The cutouts 6 run vertically through the chip module 600, and each of the cutouts 6 is used to accommodate one of the foolproof blocks 19, such that the contact points on the chip module 600 are one-to-one correspondingly electrically connected to the terminals 3. By providing the foolproof blocks 19 on the insulating body 1 to match with the cutouts 6, the positioning and foolproof functions may be achieved before the chip module 600 is accommodated in the insulating body 1.

As shown in FIG. 4, FIG. 5 and FIG. 8, each of the two side walls 11 is provided with an opening slot 20 at each of the front side and the back side of the corresponding reserved slot 14. Each of the opening slots 20 is provided to be farther away from the corresponding reserved slot 14 than the notch 142 located at a same side of the corresponding reserved slot 14 in the front-rear direction X (also referring to FIG. 6 and FIG. 9). The opening slots 20 are in communication with the accommodating cavity 13 along the left-right direction Y. That is, each of the opening slots 20 is concavely formed outward from the inner surface 111 of the corresponding side wall 11, and extends downward to be below the top surface of the bottom wall 10.

As shown in FIG. 4, FIG. 5 and FIG. 8, the insulating body 1 further includes four supporting blocks 21 protruding upward from the top surface of the bottom wall 10. The four supporting blocks 21 are all located in the accommodating cavity 13, and a top surface of each of the four supporting blocks 21 are located on a same horizontal plane. The supporting blocks 21 are used to support the chip module 600. In the left-right direction Y, two of the supporting blocks 21 are located at a left side and a right side of the accommodating cavity 13, and are respectively provided to align with the two reserved slots 14 of the two side walls 11. The two of the supporting blocks 21 are provided to one-to-one correspond and to be respectively adjacent to the two reserved slots 14 of the two side walls 11 in the left-right direction Y. Each of the two supporting blocks 21 located at the left side and the right side of the accommodating cavity 13 is located between the two interior walls 141 of the corresponding reserved slot 14 in the front-rear direction X.

As shown in FIG. 4, FIG. 7 and FIG. 10, the top surfaces of the two supporting blocks 21 located at the left side and the right side of the accommodating cavity 13 are lower than the top surfaces of the two side walls 11 and higher than the inner edges 151 of the oblique surfaces 15 in the vertical direction Z. The top surfaces of the two supporting blocks 21 located at the left side and the right side of the accommodating cavity 13 and the lower edges 1423 of the two notches 142 are located on the same horizontal plane. The two supporting blocks 21 located at the left side and the right side of the accommodating cavity 13 are provided to be partially staggered in the left-right direction Y. Each of the two supporting blocks 21 located at the left side and the right side of the accommodating cavity 13 is provided to be farther away from the corresponding inner edge 151 than the inner surface 111 of the corresponding side wall 11 (also referring to FIG. 6 and FIG. 9). Each of the two supporting blocks 21 located at the left side and the right side of the accommodating cavity 13 and the inner surface 111 of the corresponding side wall 11 are provided separately in the left-right direction Y. In the front-rear direction, a distance between each of the two supporting blocks 21 located at the left side and the right side of the accommodating cavity 13 and one of the two interior walls 11 at the front side and the back side of the corresponding reserved slot 14 is less than a distance between each of the two supporting blocks 21 and the other of the two interior walls 11 at the front side and the back side of the corresponding reserved slot 14. Specifically, the supporting block 21 adjacent to the side wall 11 at the left side of the accommodating cavity 13 is provided to be close to the interior wall 141 at the front side of the corresponding reserved slot 14 and away from the interior wall 141 at the back side of the corresponding reserved slot 14 in the front-rear direction X, and the supporting block 21 adjacent to the side wall 11 at the right side of the accommodating cavity 13 is also provided to be close to the interior wall 141 at the front side of the corresponding reserved slot 14 and away from the interior wall 141 at the back side of the corresponding reserved slot 14 in the front-rear direction X. However, the supporting block 21 adjacent to the side wall 11 at the left side of the accommodating cavity 13 is provided to be closer to the interior wall 141 at the front side of the corresponding reserved slot 14 in the front-rear direction X than the supporting block 21 adjacent to the side wall 11 at the right side of the accommodating cavity 13.

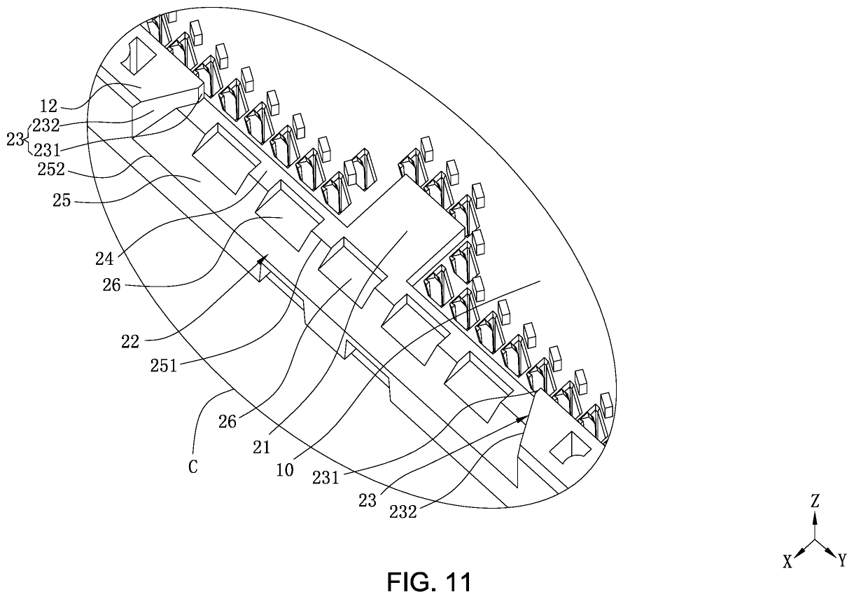

As shown in FIG. 4 and FIG. 11, each of the two end walls 12 is correspondingly formed with a through slot 22 downward concavely provided on a top surface of each of the two end walls 12. The through slot 22 runs through the corresponding end wall 12 along the front-rear direction X and is in communication with the accommodating cavity 13. The two through slots 22 of the two end walls 12 are provided opposite to each other along the front-rear direction X, and each through slot 22 is located substantially at a middle location of the corresponding end wall 12. The insulating body 1 is provided with two side surfaces 23 at the left side and the right side of each through slot 22. Each of the side surfaces 23 includes a vertical surface 231 and a sloped surface 232 connected to each other in the front-rear direction X. The vertical surface 231 is provided closer to the accommodating cavity 13 than the sloped surface 232 in the front-rear direction X. Specifically, the vertical surface 231 is connected inward to an inner surface of the corresponding end wall 12, and the sloped surface 232 is connected outward to the outer surface of the insulating body 1. The vertical surface 231 and the inner surface of the corresponding end wall 12 are perpendicular to each other. The two sloped surfaces 232 expand outward from inside thereof respectively toward the left side and the right side in the left-right direction Y.

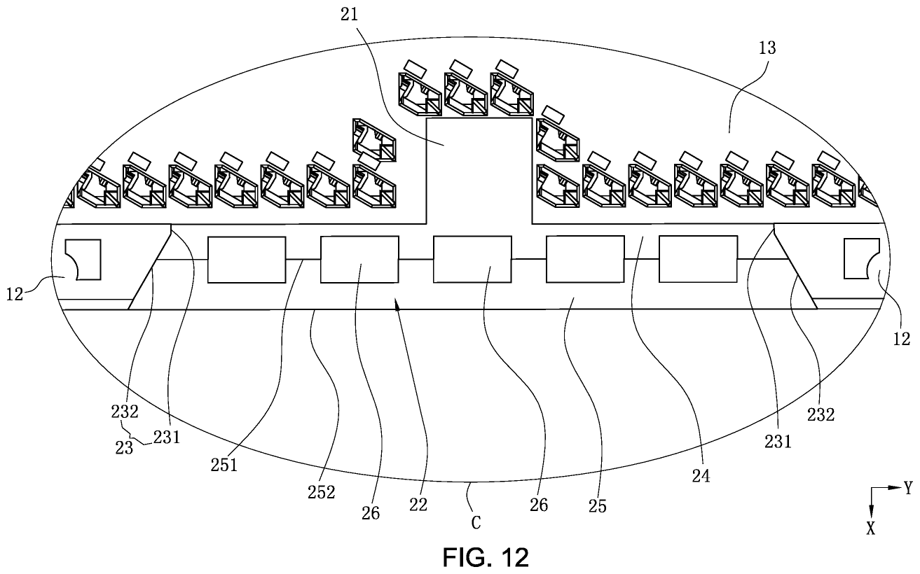

As shown in FIG. 4, FIG. 11 and FIG. 12, the insulating body 1 is provided with a straight surface 24 and an inclined surface 25 connected in the front-rear direction at a bottom portion of the through slot 22. The straight surface 24 is provided closer to the accommodating cavity 13 than the inclined surface 25. Specifically, the straight surface 24 extends horizontally, and a side of the straight surface 24 close to the accommodating cavity 13 is flush with the inner wall of the corresponding end wall 12 in the left-right direction. The straight surface 24 is provided to be lower than the top surface of the corresponding end wall 12 and higher than the top surface of the bottom wall 10 in the vertical direction Z. The inclined surface 25 is provided obliquely downward and outward from the straight surface 24 in the front-rear direction X. Specifically, an inclined angle of the inclined surface 25 is 50°. The inclined surface 25 has an inner side edge 251 and an outer side edge 252 provided opposite to each other in the front-rear direction X. The outer side edge 252 is provided farther away from the accommodating cavity 13 than the inner side edge 251 in the front-rear direction X. The inner side edge 251 is located on the straight surface 24. The inner side edge 251 is provided to be higher than the top surface of the bottom wall 10 in the vertical direction Z. In the front-rear direction X, the inner side edge 251 is provided farther away from the accommodating cavity 13 than the inner surface of the corresponding end wall 12. The outer side edge 252 is provided to be lower than the top surface of the bottom wall 10, and the outer side edge 252 is flush with the outer surface of the insulating body 1 in the front-rear direction X.

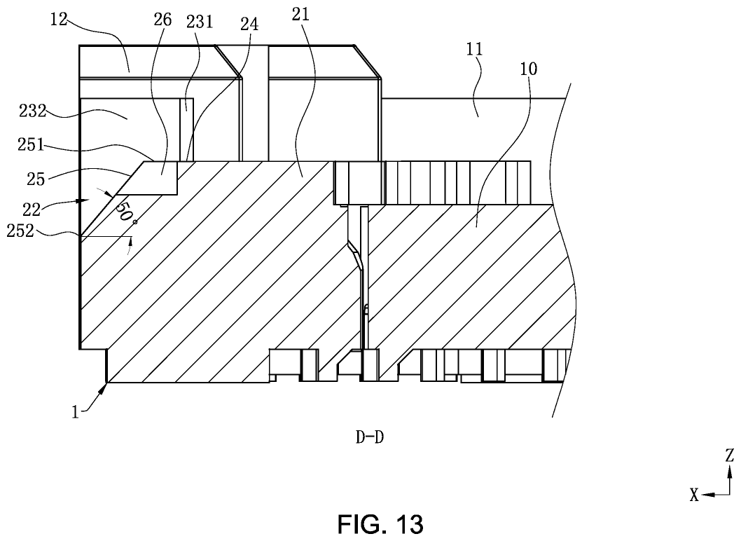

As shown in FIG. 11, FIG. 12 and FIG. 13, the insulating body 1 is further downward concavely provided with a plurality of openings 26 on each of the inclined surfaces 25. The openings 26 are provided in a row along the left-right direction Y, and the openings 26 extend toward the accommodating cavity 13 beyond the inner side edge 251 in the front-rear direction. That is, in the front-rear direction X, a portion of each of the openings 26 is downward concavely formed on the corresponding inclined surface 25, and another portion of the each of the openings 26 is downward concavely formed on the bottom wall 10. The portion of each of the openings 26 downward concavely formed on the corresponding inclined surface 25 runs outward through the corresponding inclined surface 25.

As shown in FIG. 11, FIG. 12 and FIG. 13, the two supporting blocks 21 located at the front side and the back side of the accommodating cavity 13 are respectively provided to align with the two through slots 22 of the two end walls 12 in the front-rear direction X. The top surface of each of the two supporting blocks 21 located at the front side and the back side of the accommodating cavity 13 and the corresponding straight surface 24 are located on the same horizontal plane and are extending and connected together. That is, in the front-rear direction, each of the two supporting blocks 21 located at the front side and the back side of the accommodating cavity 13 and the corresponding through slot 22 are not provided separately. Further, each of the two supporting blocks 21 located at the front side and the back side of the accommodating cavity 13 is located between the two side surfaces 23 of the corresponding through slot 22 in the left-right direction Y.

As shown in FIG. 1 and FIG. 2, the clip tool 4 includes a clip seat 41 provided at the back side of the insulating body 1 and mounted on the circuit board 700, an upper cover 42 provided above the insulating body 1, and a rocking shaft 43 used to connect the clip seat 41 and the upper cover 42. The rocking shaft 43 includes a pivot shaft 431 and a driving shaft 432 provided and connected in an L-shape. The pivot shaft 431 of the rocking shaft 43 passes through the clip seat 41 and the upper cover 42 along the left-right direction Y to connect the clip seat 41 and the upper cover 42, such that the pivot shaft 431 is pivoted to the clip seat 41, and the pivot shaft 431 is connected to the upper cover 42. In the using process, by rotating the driving shaft 432 connected to the pivot shaft 431, the pivot shaft 431 rotates in the clip seat 41, and drives the upper cover 42 connected to the pivot shaft 431 to rotate relative to the clip seat 41 at the back side of the insulating body 1, thus facilitating the upper cover 42 to rotatably open and close above the insulating body 1. The dust cover 5 is used to prevent the insulating body 1 and the terminals 3 from dust contamination when the chip module 600 is not mounted in the insulating body 1, and is removed from the upper side of the upper cover 42 when the chip module 600 is mounted to the insulating body 1.

As shown in FIG. 1 and FIG. 2, a back plate 800 is further provided below the circuit board 700. A screw bolt sequentially passes the clip seat 41 and the circuit board 700 downward from top thereof, and is screwed to a thread of the back plate 800, thus fixing the clip seat 41 to the circuit board 700. Another screw bolt sequentially passes the upper cover 42 and the circuit board 700 downward from top thereof, and is screwed to a thread of the back plate 800, thus tightly locking the upper cover 42 to be above the insulating body 1, and ensuring the chip module 600 to be stably positioned in the insulating body 1 and in contact with the terminals 3.

To sum up, the electrical connector according to certain embodiments of the present invention has the following beneficial effects:

1) Compared with the related art, in certain embodiments of the present invention, the insulating body 1 is provided with the oblique surfaces 15 respectively at the bottom portions of the reserved slots 14. The oblique surfaces 15 may guide the fingers of a user inward from outside thereof to move toward the chip module 600 in the insulating body 1, and to move to the left side and the right side of the chip module 600, thus enhancing the convenience for the user to retrieve the chip module 600 in the insulating body 1. Further, the outer edge of each of the oblique surfaces 15 at the bottom portions of the reserved slots 14 is provided to be lower than the top surface of the bottom wall 10, and in the vertical direction Z, the space receiving each of the fingers of the user is enlarged, and the user may retrieve the chip module 600 using the finger pulps. Compared to the related art in which the user retrieves the chip module 600 using the fingertips, the finger pulps allow the human hand to stably apply a clamping force to the chip module 600, such that the chip module 600 does not easily slip and fall from the fingers of the user. Moreover, each of the two side walls 11 is further concavely provided with the notches 142 at the front side and the back side of the corresponding reserved slot 14 in the front-rear direction X. Compared to the related art in which the two interior walls 141 at the front side and the back side of the reserved slot 14 extend as vertical plain surfaces, the space for each of the two reserved slots 14 in the front-rear direction X is enlarged, which is convenient for receiving a large part of the finger to retrieve the chip module 600 in the insulating body 1, and further ensuring the chip module 600 not to easily slip downward from the fingers of the user in the retrieving process.

2) Each of the two notches 142 runs through the corresponding side wall 11 in a left-right direction Y, and each of the two notches 142 includes a curved surface 1421. Each of the curved surface 1421 is connected inward to an inner surface 111 of the corresponding side wall 11, and is connected outward to an outer surface of the corresponding side wall 11. The curved surface 1421 smoothly passes from the interior walls 141 of the corresponding reserved slot 14 to the top surface of the corresponding side wall 11 in the front-rear direction, such that when the fingers of the user retrieve the chip module 600 in the insulating body 1 inward from outside thereof, each finger smoothly passes the reserved slot 14, and is not abrased by the sharp right angle at the two sides of the reserved slot 14.

3) Each of the two notches 142 further includes a plain surface 1422 located above the curved surface 1421 extending vertically. Compared to the case where the curved surface 1421 is individually provided, by having the plain surface 1422 extending vertically and connected to be above the curved surface 1421, the width of each of the two notches 142 in the front-rear direction is reduced, preventing each of the two notches 142 from extending to the opening slots 20 at the same side of the corresponding reserved slot 14 along the front-rear direction X, thus increasing the strength of each of the two side walls 11, and better preventing the insulating body 1 from warping.

4) The supporting blocks 21 protrude upward from the top surface of the bottom wall 10, and the top surface of each of the four supporting blocks 21 is lower than the top surface of each of the two side walls 11 and higher than the inner edge 151 of the oblique surface 15. The top surfaces of the supporting blocks 21 are used to support the chip module 600. Thus, a gap is provided between the inner edge 151 each of the oblique surfaces 15 and the bottom surface of the chip module 600, such that the fingers of the user may insert into the gaps and bend opposite each other below the chip module 600 to clamp the chip module 600, thereby providing an upward acting force to the chip module 600, such that the user may stably retrieve the chip module 600 in the insulating body 1, preventing the chip module 600 from slipping and falling between the fingers of the user, damaging the terminals, and causing the damage to the chip module 600.

5) Each of the two end walls 12 located at the front side and the back side of the accommodating cavity 13 is further correspondingly formed with the through slot 22. The through slot 22 runs through the corresponding end wall 12 along the front-rear direction X. The insulating body 1 is provided with the inclined surface 25 at the bottom portion of the through slot 22. The inclined surface 25 is provided obliquely downward and outward from the straight surface 24 in the front-rear direction X. Thus, the user may retrieve the chip module 600 in the insulating body 1 from the left side and the right side of the insulating body 1, and further may retrieve the chip module 600 in the insulating body 1 from the front side and the back side of the insulating body 1, further enhancing the convenience for the user to retrieve the chip module 600.

6) The clip seat 41 is provided at the back side of the insulating body 1, and the upper cover 42 may only rotate relative to the clip seat 41 with the rocking shaft 43 at the back side of the insulating body 1 as the rotation axis. The two reserved slot 14 are located at the left side and the right side of the insulating body 1. Thus, after the upper cover 42 is open, when the user retrieves the chip module 600 at the left side and the right side of the insulating body 1, the user is not blocked by the upper cover 42 or the clip seat 41, further enhancing the convenience for the user to retrieve the chip module 600.

7) Each of the two supporting blocks 21 located at the left side and the right side of the accommodating cavity 13 is located between the two interior walls 141 of the corresponding reserved slot 14 in the front-rear direction X, such that the fingers of the user may insert below the chip module 600 at the front side and the back side of the supporting blocks 21 toward the left-right direction, providing an upward acting force to the chip module 600, such that the user may stably retrieve the chip module 600 in the insulating body 1.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An electrical connector, configured to be electrically connected to a chip module, the electrical connector comprising:
an insulating body, having a bottom wall, an accommodating cavity provided above the bottom wall, and two side walls protruding upward relative to the bottom wall and provided at a left side and a right side of the accommodating cavity; and
a plurality of terminals, provided in the insulating body, and configured to be electrically connected to the chip module,
wherein each of the two side walls is correspondingly formed with a reserved slot downward concavely provided on a top surface of each of the two side walls, the reserved slot runs through a corresponding one of the two side walls in a left-right direction and is in communication with the accommodating cavity, the insulating body is provided with an oblique surface at a bottom portion of the reserved slot, the oblique surface is provided obliquely downward and outward, the oblique surface has an inner edge and an outer edge provided opposite to each other in the left-right direction, the outer edge is provided farther away from the accommodating cavity than the inner edge, the outer edge is provided to be lower than a top surface of the bottom wall, each of the two side walls is further concavely provided with two notches at a front side and a back side of the corresponding reserved slot respectively in a front-rear direction, each of the two notches runs along the left-right direction and upward through the corresponding one of the two side walls, and a lower edge of each of the two notches is provided to be higher than the corresponding oblique surface in a vertical direction.

2. The electrical connector according to claim 1, wherein each of the two notches has a curved surface, two interior walls are respectively provided at the front side and the back side of the reserved slot, and the curved surface of each of the two notches is downward connected to a corresponding one of the two interior walls.

3. The electrical connector according to claim 2, wherein each of the two notches further has a plain surface extending vertically, the plain surface is located above the curved surface and is connected to the curved surface, and the plain surface of each of the two notches is upward connected to the top surface of the corresponding one of the two side walls.

4. The electrical connector according to claim 2, wherein the curved surface of one of the two notches at the front side and the back side of the reserved slot of each of the two side walls is downward concavely provided with a groove, and the groove is in communication with the corresponding reserved slot in the front-rear direction.

5. The electrical connector according to claim 4, wherein the groove extends downward to pass beyond the oblique surface.

6. The electrical connector according to claim 4, wherein each of the two side walls is provided with a foolproof block protruding into the accommodating cavity to match with a cutout of the chip module, the foolproof block and the other of the notches not provided with the groove are located at a same side of the corresponding reserved slot in the front-rear direction, and the foolproof block is provided to be farther away from the corresponding reserved slot than the other of the notches not provided with the groove.

7. The electrical connector according to claim 4, wherein the two grooves located on the two side walls are provided to align in the left-right direction.

8. The electrical connector according to claim 1, wherein the oblique surface is further downward concavely provided with a recess, and the recess extends toward the accommodating cavity in the left-right direction and passes beyond the inner edge.

9. The electrical connector according to claim 8, wherein the oblique surface is further downward concavely provided with a plurality of concave portions, the concave portions are provided in a row along the front-rear direction, and the concave portions are located at a same side of the recess in the front-rear direction.

10. The electrical connector according to claim 1, wherein each of the two side walls is provided with an opening slot at the front side or the back side of the corresponding reserved slot, the opening slot is provided to be farther away from the corresponding reserved slot than one of the two notches located at a same side of the corresponding reserved slot in the front-rear direction, and the opening slot is in communication with the accommodating cavity along the left-right direction.

11. The electrical connector according to claim 1, wherein the inner edge is provided to be farther away from the accommodating cavity than an inner surface of the corresponding one of the two side walls.

12. The electrical connector according to claim 1, wherein the outer edge is provided to be flush with an outer surface of the insulating body.

13. The electrical connector according to claim 1, wherein the oblique surface is provided obliquely downward and outward from the top surface of the bottom wall.

14. The electrical connector according to claim 1, wherein the insulating body further comprises a supporting block protruding upward relative to the bottom wall, the supporting block is located in the accommodating cavity to support the chip module, and a top surface of the supporting block is lower than the top surface of each of the two side walls and higher than the inner edge of the oblique surface in the vertical direction.

15. The electrical connector according to claim 14, wherein the lower edge of each of the two notches and the top surface of the supporting block are located on a same horizontal plane.

16. The electrical connector according to claim 14, wherein the supporting block is provided to align with the two reserved slots of the two side walls in the left-right direction.

17. The electrical connector according to claim 16, wherein the insulating body is provided with two supporting blocks, the two supporting blocks are provided at a left side and a right side of the accommodating cavity, each of the two supporting blocks is provided to be adjacent to a corresponding one of the two reserved slots of the two side walls, a distance between each of the two supporting blocks and one of two interior walls at the front side and the back side of the corresponding one of the two reserved slots of the two side walls is less than a distance between each of the two supporting blocks and the other of the two interior walls at the front side and the back side of the corresponding one of the two reserved slots of the two side walls.

18. The electrical connector according to claim 14, wherein the supporting block is provided to be farther away from the corresponding inner edge than an inner surface of the corresponding one of the two side walls, and the supporting block and the inner surface of the corresponding one of the two side walls are provided separately in the left-right direction.

19. The electrical connector according to claim 1, further comprising a clip tool, wherein the clip tool comprises an upper cover and a clip seat, the clip seat is provided at one of a front side and a back side of the insulating body, and the upper cover is provided above the insulating body and rotates relative to the clip seat at one of a front side and a back side of the accommodating cavity.

20. The electrical connector according to claim 1, wherein the insulating body is provided with two end walls respectively at a front side and a back side of the accommodating cavity, each of the two end walls connects the two side walls, each of the two end walls is correspondingly formed with a through slot downward concavely provided on a top surface of each of the two end walls, the through slot runs through a corresponding one of the two end walls along the front-rear direction and is in communication with the accommodating cavity, the insulating body is provided with an inclined surface at a bottom portion of the through slot, and the inclined surface is provided obliquely downward and outward in the front-rear direction.
